(19) United States
(12) Patent Application Publication
(10) Pub. No.: US 2013/0015906 A1
(43) Pub. Date: Jan. 17, 2013

(54) Touch Panel Device

(71) Applicant: Ying-Jyh Yeh, Kaohsiung City (TW)

(72) Inventor: Ying-Jyh Yeh, Kaohsiung City (TW)

(73) Assignee: Silicon Integrated Systems Corp., Hsinchu City (TW)

(21) Appl. No.: 13/182,436

(22) Filed: Jul. 13, 2011

(51) Int. Cl. H03K 17/96

(52) U.S. Cl. 327/517

(57) ABSTRACT

A touch panel device includes a touch panel and a controller. The touch panel includes a first region and a second region. The first region includes a plurality of first driving conductors extended along a first direction, and a plurality of first sensing conductors extended along a second direction perpendicular to the first direction. The second region includes a plurality of second driving conductors extended along the first direction, and a plurality of second sensing conductors extended along the second direction. The controller is used for outputting a plurality of driving signals in an ordered sequence of the second direction to drive the plurality of first driving conductors and the plurality of second driving conductors, and for receiving a plurality of sensing signals from the plurality of first sensing conductors and the plurality of second sensing conductors in an ordered sequence of the first direction.

### BACKGROUND OF THE INVENTION

1. Field of the Invention

The present invention relates to a touch panel device, and more particularly, to a touch panel device having a large size touch panel with a novelty driving scheme.

2. Description of the Prior Art

Advanced displays have gradually become a major feature of today's consumer electronics products. To facilitate portability and utilization, a display device having a touch panel for users to touch directly have been widely used in television sets, smart phones or other electronics products.

To facilitate portability and utilization, a touch panel for a user to touch directly has been the focus in market development. A liquid crystal display (LCD) for a smart phone is usually combined with a touch panel, so that push buttons or function keys can be omitted. The touch panel uses electrical signals to control image displays and functions of the LCD. The electrical signals are produced after the user touches the outer surface of the touch panel.

Referring to FIG. 1, FIG. 1 is a schematic diagram of a touch panel device 10 having a conventional touch panel 11. The touch panel 11 of the touch panel device 10 comprises a sensor array 12 for detecting a touch position and strength of a finger or a pen as it touches the panel. When the finger touches the panel, the resistance or the capacitance of the sensor array 12 made from resistors or capacitors varies. For example, the distance between the upper and lower electrodes will be reduced as the finger press down on the outer surface of the touch panel 11 made from flexible materials, causing the resistance between the upper and lower electrodes to change. Or, the human body capable of conducting electricity will influence the capacitor between the upper and lower electrodes or change the capacitance between upper and lower electrodes as the finger press down on the outer surface of the touch panel 11. By detecting the touch position and the strength of the finger as it touches the panel, variations in the resistance or the capacitance can be measured.

The sensor array 12 is formed by a set of conductors in the X-direction interlaced with a set of conductors in the Y-direction, or is formed by stripped conductors arranged circularly in polar coordinates. Each of the intersections of the X-direction conductors and the Y-direction conductors may be equivalent to a resistor or a capacitor. A controller 14 outputs a driving signal to conduct conductors in one row through the multiplexer 16, and sensing signals of the intersections in each column are sent back to the controller 14 through a multiplexer 18. Accordingly, the touch position and strength of an applied force can be measured by detecting the variety of sensing signals.

Before the user's finger presses down on a point on the outer surface of the touch panel 11, the stripped conductors in the X-direction and in the Y direction have the same potential. Meanwhile, no electric current flows through the touch panel 11. Once the user's finger touches the touch panel 11, the user's body will generate a very small amount of electric current, causing the capacitance which a plurality of nodes neighboring the touch point correspond to change. The controller 14 determines the touched intersections by detecting the variation in ratio between the capacitance of the plurality of the intersections and the capacitance of the touch panel 11. The variation in the capacitance of each of the intersections is not obvious, so the variation in ratio between the capacitance of the plurality of the touched nodes and the capacitance of the touch panel 11 is not obvious, either. Thus, the controller 14 has to be highly sensitive. Since the capacitance of the whole touch panel 11 is proportion to the size of the touch panel 11, the controller 14 requires higher sensitivity to measure the variety of the sensing signal when using a large-size touch panel 11. That increases more cost and complexity of design of the controller 14.

### SUMMARY OF THE INVENTION

According to the present invention, a touch panel device comprises a touch panel and a controller. The touch panel comprises a first region and a second region. The first region comprises a plurality of first driving conductors extended along a first direction, and a plurality of first sensing conductors extended along a second direction perpendicular to the first direction. The second region comprises a plurality of second driving conductors extended along the first direction, and a plurality of second sensing conductors extended along the second direction. The controller is used for outputting a plurality of driving signals in an ordered sequence of the second direction to drive the plurality of first driving conductors and the plurality of second driving conductors, and for receiving a plurality of sensing signals from the plurality of first sensing conductors and the plurality of second sensing conductors in an ordered sequence of the first direction.

In one aspect of the present invention, the touch panel device further comprises a plurality of first driving lines electrically connected to the plurality of first driving conductors, a plurality of second driving lines electrically connected to the plurality of second driving conductors, a plurality of first sensing lines electrically connected to the plurality of first sensing conductors, and a plurality of second sensing lines electrically connected to the plurality of second sensing conductors. Each of the first driving lines is electrically connected to one of the second driving lines. The controller comprises a controller electrically connected to the first driving lines, the second driving lines, the first sensing lines, and the second sensing lines. The controller is used for outputting the plurality of driving signals via the first driving lines and the second driving lines to drive the plurality of first driving conductors and the plurality of second driving conductors, and for receiving the plurality of sensing signals from the plurality of first sensing conductors and the plurality of second sensing conductors.

In one aspect of the present invention, the controller comprises a first controller electrically connected to the first driving lines and the first sensing lines, and a second controller electrically connected to the second driving lines and the second sensing lines. The first and second controllers are used for outputting the plurality of driving signals via the first driving lines and the second driving lines to drive the plurality of first driving conductors and the plurality of second driving conductors, and for receiving the plurality of sensing signals from the plurality of first sensing conductors and the plurality of second sensing conductors.

According to the present invention, a touch panel device comprises a touch panel and a controller. The touch panel comprises a first region, a second area, a third area, and a fourth area. The first area comprises a plurality of first driving conductors extended along a first direction, and a plurality of first sensing conductors extended along a second direction perpendicular to the first direction. The second region comprises a plurality of second driving conductors extended along the first direction, and a plurality of second sensing conductors extended along the second direction. The third region comprises a plurality of third driving conductors extended along the first direction, and a plurality of third sensing conductors extended along the second direction. The fourth region comprises a plurality of fourth driving conductors extended along the first direction, and a plurality of fourth sensing conductors extended along the second direction. The controller is used for outputting a plurality of driving signals to drive the plurality of first driving conductors and the plurality of second driving conductors in an ordered sequence of the second direction, to drive the plurality of third driving conductors, the plurality of fourth driving conductors in an ordered sequence of a third direction opposite to the second direction, and for receiving a plurality of sensing signals from the plurality of first sensing conductors, the plurality of second sensing conductors, the plurality of third sensing conductors, the plurality of fourth sensing conductors.

In one aspect of the present invention, a number of the first driving conductors, a number of the second driving conductors, a number of the third driving conductors, and a number of the fourth driving conductors are identical, and a number of the first sensing conductors, a number of the second sensing conductors, a number of the third sensing conductors, and a number of the fourth sensing conductors are identical.

In one aspect of the present invention, the touch panel device further comprises a plurality of first driving lines electrically connected to the plurality of first driving conductors, a plurality of second driving lines electrically connected to the plurality of second driving conductors, a plurality of first sensing lines electrically connected to the plurality of first sensing conductors, a plurality of second sensing lines electrically connected to the plurality of second sensing conductors, a plurality of third driving lines electrically connected to the plurality of third driving conductors, a plurality of fourth driving lines electrically connected to the plurality of fourth driving conductors, a plurality of third sensing lines electrically connected to the plurality of third sensing conductors, and a plurality of fourth sensing lines electrically connected to the plurality of fourth sensing conductors.

In one aspect of the present invention, each of the first driving lines is electrically connected to one of the second driving lines, and each of the third driving lines is electrically connected to one of the fourth driving lines.

In one aspect of the present invention, the controller comprises a first controller and a second controller. The first controller electrically connected to the first driving lines, the second driving lines, the first sensing lines, and the second sensing lines, is used for outputting the plurality of driving signals via the first driving lines and the second driving lines to drive the plurality of first driving conductors and the plurality of second driving conductors, for receiving the plurality of sensing signals from the plurality of first sensing conductors in an ordered sequence of a fourth direction opposite to the first direction, and for receiving the plurality of sensing signals from the plurality of second sensing conductors in an ordered sequence of the first direction. The second controller electrically connected to the third driving lines, the fourth driving lines, the third sensing lines, and the fourth sensing lines, is used for outputting the plurality of driving signals via the third driving lines and the fourth driving lines to drive the plurality of third driving conductors and the plurality of fourth driving conductors, for receiving the plurality of sensing signals from the plurality of third sensing conductors in an ordered sequence of the fourth direction, and for receiving the plurality of sensing signals from the plurality of fourth sensing conductors in an ordered sequence of the first direction.

In one aspect of the present invention, the controller comprises a first controller electrically connected to the first driving lines and the first sensing lines, a second controller electrically connected to the second driving lines and the second sensing lines, a third controller electrically connected to the third driving lines and the third sensing lines, and a fourth controller electrically connected to the fourth driving lines and the fourth sensing lines. The first controller is used for outputting the plurality of driving signals via the first driving lines to drive the plurality of first driving conductors in an ordered sequence of the second direction, and for receiving the plurality of sensing signals from the plurality of first sensing conductors in an ordered sequence of a fourth direction opposite to the first direction. The second controller is used for outputting the plurality of driving signals via the second driving lines to drive the plurality of second driving conductors in an ordered sequence of the second direction, and for receiving the plurality of sensing signals from the plurality of second sensing conductors in an ordered sequence of the first direction. The third controller is used for outputting the plurality of driving signals via the third driving lines to drive the plurality of third driving conductors in an ordered sequence of the third direction, and for receiving the plurality of sensing signals from the plurality of third sensing conductors in an ordered sequence of the fourth direction. The fourth controller is used for outputting the plurality of driving signals via the fourth driving lines to drive the plurality of fourth driving conductors in an ordered sequence of the third direction, and for receiving the plurality of sensing signals from the plurality of fourth sensing conductors in an ordered sequence of the first direction.

In one aspect of the present invention, the controller comprises a first controller electrically connected to the first driving lines and the first sensing lines, a second controller electrically connected to the second driving lines and the second sensing lines, a third controller electrically connected to the third driving lines and the third sensing lines, and a fourth controller electrically connected to the fourth driving lines and the fourth sensing lines. The first controller is used for outputting the plurality of driving signals via the first driving lines to drive the plurality of first driving conductors in an ordered sequence of the second direction, and for receiving the plurality of sensing signals from the plurality of first sensing conductors in an ordered sequence of the first direction. The second controller is used for receiving the plurality of sensing signals from the plurality of second sensing conductors in an ordered sequence of the first direction. The third controller is used for outputting the plurality of driving signals via the third driving lines to drive the plurality of third driving conductors in an ordered sequence of the second direction, and for receiving the plurality of sensing signals from the plurality of third sensing conductors in an ordered sequence of the first direction. The fourth controller electrically connected to the fourth driving lines and the fourth sensing lines is used for receiving the plurality of sensing signals from the plurality of fourth sensing conductors in an ordered sequence of the first direction.

In contrast to the prior art, the touch panel device having a touch panel comprising two or more region. Since at least one controller outputs driving signals via the driving lines to each driving conductors in multiple regions simultaneously, the scan rate is increased. In addition, since each controller controls one half or one fourth of the area of the touch panel, and is responsible for one half of the capacitance of the touch panel, the touch panel device can be well controlled by the controller without using a single controller with higher detecting sensibility and cost.

These and other features, aspects and advantages of the present disclosure will become understood with reference to the following description, appended claims and accompanying figures.

### BRIEF DESCRIPTION OF THE DRAWINGS

FIG. 1 is a schematic diagram of a touch panel device 10 having a conventional touch panel.

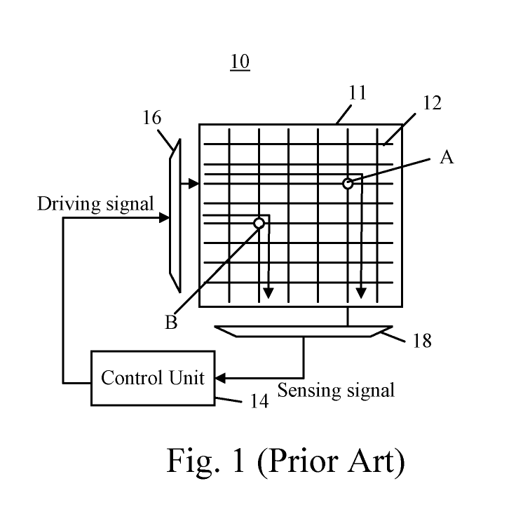

FIG. 2 illustrates a functional block diagram of a touch panel device according to a first embodiment of the present invention.

FIG. 3 shows a touch panel shown in FIG. 2.

FIG. 4 illustrates a functional block diagram of a touch panel device according to a second embodiment of the present invention.

FIG. 5 illustrates a functional block diagram of a touch panel device according to a third embodiment of the present invention.

FIG. 6 shows a touch panel shown in FIG. 5.

FIG. 7 illustrates a functional block diagram of a touch panel device according to a fourth embodiment of the present invention.

FIG. 8 illustrates a functional block diagram of a touch panel device according to a fifth embodiment of the present invention.

### DETAILED DESCRIPTION OF THE PREFERRED EMBODIMENTS

The following embodiments are exemplified by referring to the accompanying drawings, for describing specific embodiments implemented by the present invention. Furthermore, directional terms described by the present invention, such as upper, lower, front, back, left, right, inner, outer, side and etc., are only directions by referring to the accompanying drawings, and thus the used directional terms are used to describe and understand the present invention, but the present invention is not limited thereto.

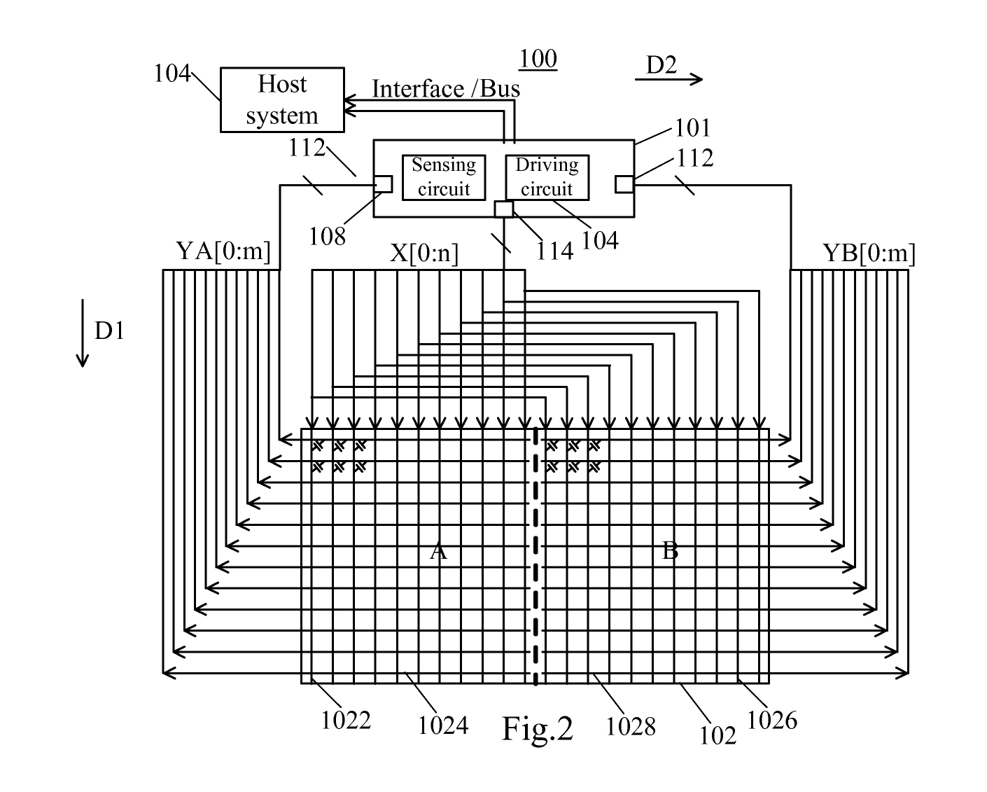

Please refer to FIG. 2, FIG. 2 illustrates a functional block diagram of a touch panel device 100 according to a first embodiment of the present invention. The touch panel device 100 comprises a control unit having a controller 101, a touch panel 102, and a host system 104. The controller 101 comprises a driving circuit 106, a sensing circuit 108, and I/O channels 112 and 114. The host system 104 is used for controlling the operation of the touch panel device 100. The controller 101, implemented by a digital signal processor (DSP) or a software program code, is used for determining a touch position and magnitude of a force applied on the touch panel 102.

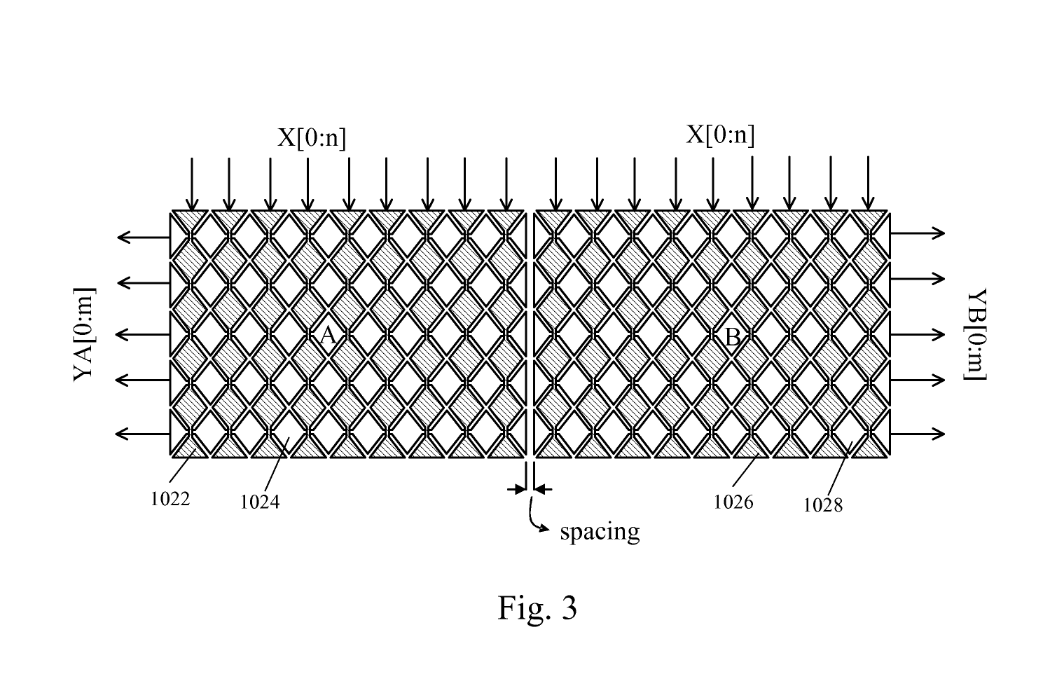

Please refer to FIG. 2 in conjunction to FIG. 3. FIG. 3 shows a touch panel shown in FIG. 2. The touch panel 102 comprises a first region A and a second region B apart from the first region A. Each of the first region A and the second region B comprise two layers of electrical conductors. The first region A comprises a plurality of first driving conductors 1022 extended along a first direction D1 (e.g. the columns of the touch panel 102), and a plurality of first sensing conductors 1024 extended along a second direction D2 (e.g. the rows of the touch panel 102) perpendicular to the first direction D1. The second region B comprises a plurality of second driving conductors 1026 extended along the first direction D1, and a plurality of second sensing conductors 1028 extended along the second direction D2. The intersections of the driving conductors 1022 and the sensing conductors 1024 or of the driving conductors 1026 and the sensing conductors 1028 are not physically and electrically contacted, forming the mutual capacitance sensing element of the touch panel 102.

A plurality of driving lines X[0:n] are electrically connected to the plurality of first driving conductors 1022 and the plurality of second driving conductors 1026. A plurality of first sensing lines YA[0:m] are electrically connected to the plurality of first sensing conductors 1024, and a plurality of second sensing lines YB[0:m] are electrically connected to the plurality of second sensing conductors 1028. The driving circuit 104 outputs driving signals via the I/O channel 114 and the driving lines X[0:n] to the touch panel 102. The sensing circuit 106, coupled to each of the sensing conductors 1024 and 1028 via the sensing lines YA[0:m] and YB[0:m], receives sensing signals, respectively.

The driving circuit 104 outputs driving signals in an ordered sequence of the second direction D2 to drive the plurality of first driving conductors 1022 and the plurality of second driving conductors 1026 simultaneously. The sensing circuit 108 receives sensing signals from the plurality of first sensing conductors 1024 and the plurality of second sensing conductors 1028 in an ordered sequence of the first direction D1. When fingers, touch pens, or other objects make one or more contacts of the touch panel 102, a certain point of the intersection of sensing conductors 1024, 1028 and the driving conductors 1022, 1026 is bound to induce a capacitance coupling phenomenon to cause the sensing signals generated by the sensing conductors 1024, 1028 to produce voltage variations. After each of the driving conductors 1022, 1026 is scanned one by one, an exact touch position can be obtained. The controller 101 determines a touch position according to the voltage variations of the sensing signals.

Since the driving circuit 104 outputs driving signals via driving lines X[0:n] to the first driving conductors 1022 in the first region A and the second driving conductors 1026 in the second region B simultaneously, the scan rate is increased. In addition, because the capacitance of each region A or B is half of the touch panel 102, the touch panel device 100 can be well controlled without increasing the detecting sensibility of the controller 101.

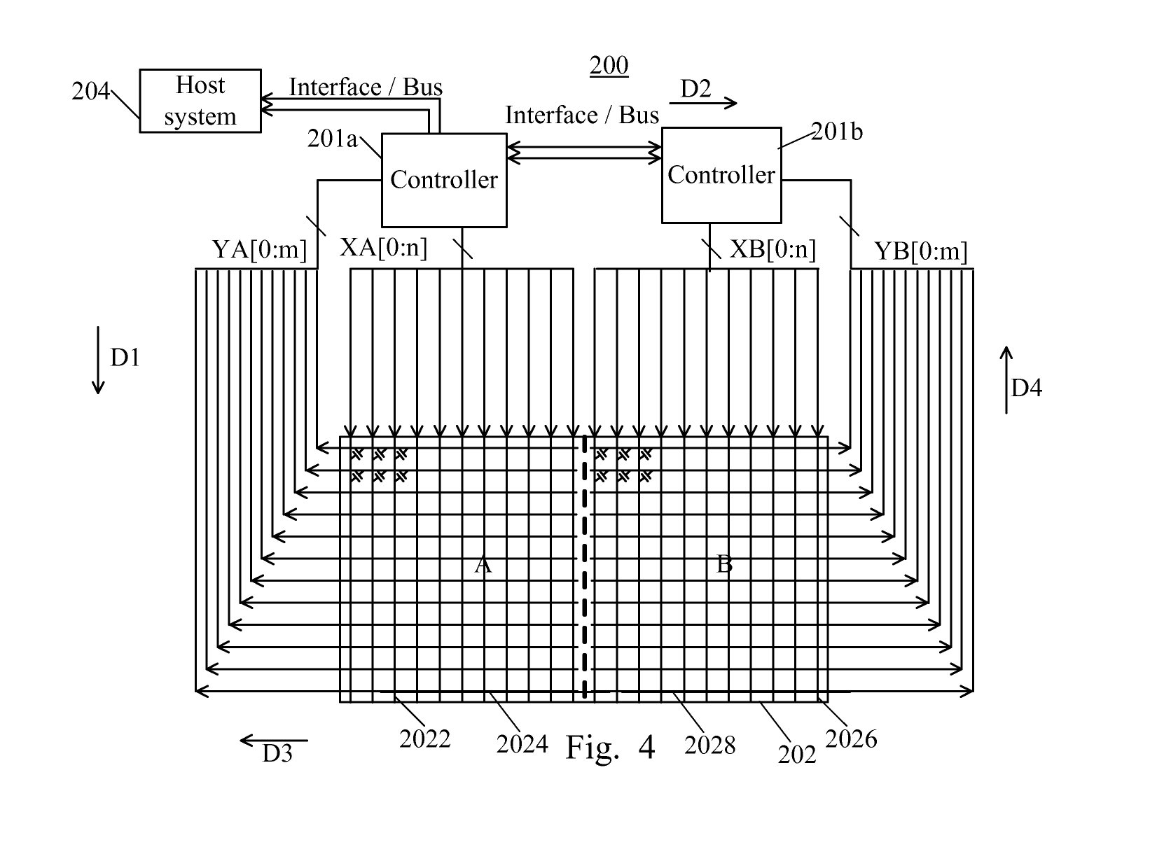

Please refer to FIG. 4, FIG. 4 illustrates a functional block diagram of a touch panel device 200 according to a second embodiment of the present invention. The touch panel device 200 comprises a control unit having two controllers 201a and 201b, a touch panel 202, and a host system 204. For brevity, each of the controllers 201a and 201b comprises a driving circuit, a sensing circuit, and I/O channels, all of which have the same function as that illustrated in FIG. 2 and are described above, so operation and label of the driving circuit and the sensing circuit is omitted. The host system 204 is used for controlling the operation of the touch panel device 200. The controllers 201a and 201b, implemented by a digital signal processor (DSP) or a software program code, is used for determining a touch position and magnitude of a force applied on the touch panel 202.

The touch panel 202 comprises a first region A and a second region B. The first region A comprises a plurality of first driving conductors 2022 extended along a first direction D1 (e.g. the columns of the touch panel 202), and a plurality of first sensing conductors 2024 extended along a second direction D2 (e.g. the rows of the touch panel 202) perpendicular to the first direction D1. The second region B comprises a plurality of second driving conductors 2026 extended along the first direction D1, and a plurality of second sensing conductors 2028 extended along the second direction D2. The intersections of the driving conductors 2022 and the sensing conductors 2024 or of the driving conductors 2026 and the sensing conductors 2028 are not physically and electrically contacted, forming the mutual capacitance sensing element of the touch panel 202.

A plurality of first driving lines XA[0:n] are electrically connected to the plurality of first driving conductors 2022, and a plurality of second driving lines XB[0:n] are electrically connected to the plurality of second driving conductors 2026. A plurality of first sensing lines YA[0:m] electrically connected to the plurality of first sensing conductors 2024, and a plurality of second sensing lines YB[0:m] electrically connected to the plurality of second sensing conductors 2028. The controller 201a outputs driving signals via the driving lines XA[0:n] to the first driving conductors 2022, while the controller 201b outputs driving signals via the driving lines XB[0:n] to the second driving conductors 2026. The controller 201a coupled to the sensing conductors 2024 via the sensing lines YA[0:m] receives sensing signals, while the controller 201b coupled to sensing conductors 2028 via the sensing lines YB[0:m] receives sensing signals.

The controller 201a outputs driving signals in an ordered sequence of the second direction D2 to drive the plurality of first driving conductors 2022, and receives sensing signals from the first sensing conductors 2024 in an ordered sequence of the first direction D1. Meanwhile, the controller 201b outputs driving signals in an ordered sequence of the second direction D2 to drive the plurality of second driving conductors 2026, and receives sensing signals from the second sensing conductors 2028 in an ordered sequence of the first direction D1. When fingers, touch pens, or other objects make one or more contacts of the touch panel 202, a certain point of the intersection of sensing conductors 2024, 2028 and the driving conductors 2022, 2026 is bound to induce a capacitance coupling phenomenon to cause the sensing signals generated by the sensing conductors 2024, 2028 to produce voltage variations. After each of the driving conductors 2022, 2026 is scanned one by one, an exact touch position can be obtained. The controllers 201a and 201b determines a touch position according to the voltage variations of the sensing signals.

Since the controllers 201a and 201b outputs driving signals via the driving lines XA[0:n] and XB[0:n] to the first driving conductors 2022 in the first region A and the second driving conductors 2026 in the second region B simultaneously, the scan rate is increased. In addition, since each of the controllers 201a and 201b controls one half of the area of the touch panel 202, meaning that each of the controllers 201a and 201b is responsible for one half of the capacitance of the touch panel 202, the touch panel device 200 can be well controlled by the controller 201a and 201b without using a single controller with higher detecting sensibility and cost.

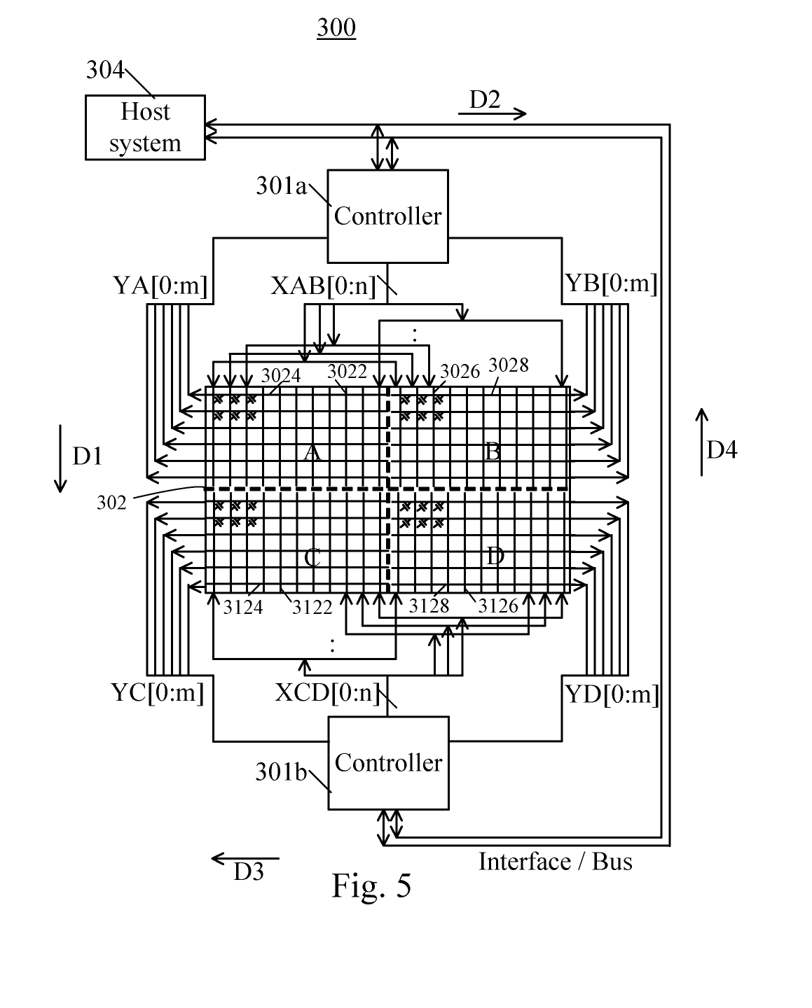

Please refer to FIG. 5, FIG. 5 illustrates a functional block diagram of a touch panel device 300 according to a third embodiment of the present invention. The touch panel device 300 comprises a control unit having two controllers 301a and 301b, a touch panel 302, and a host system 304. For brevity, each of the controllers 301a and 301b comprises a driving circuit, a sensing circuit, and I/O channels, all of which have the same function as that illustrated in FIG. 2 and are described above, so operation and label of the driving circuit and the sensing circuit is omitted. The host system 304 is used for controlling the operation of the touch panel device 300. The controllers 301a and 301b, implemented by a digital signal processor (DSP) or a software program code, is used for determining a touch position and magnitude of a force applied on the touch panel 302.

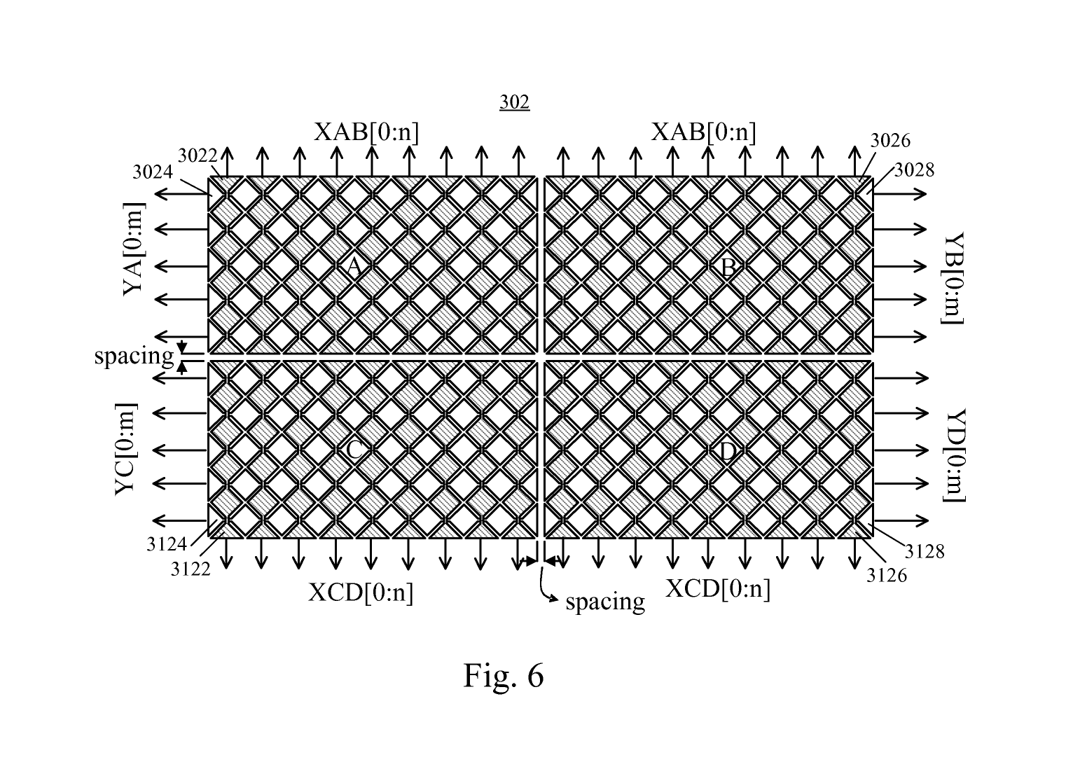

Please refer to FIG. 5 and FIG. 6. FIG. 6 shows a touch panel shown in FIG. 5. The touch panel 302 comprises a first region A, a second region B, a third region C, and a fourth D, each of which is apart from the others. Each of the first region A, the second region B, the third region C, and the fourth region D comprises two layers of electrical conductors. The first region A comprises a plurality of first driving conductors 3022 extended along a first direction D1 (e.g. the columns of the touch panel 302), and a plurality of first sensing conductors 3024 extended along a second direction D2 (e.g. the rows of the touch panel 302) perpendicular to the first direction D1. The second region B comprises a plurality of second driving conductors 3026 extended along the first direction D1, and a plurality of second sensing conductors 3028 extended along the second direction D2. The third region C comprises a plurality of third driving conductors 3122 extended along the first direction D1 (e.g. the columns of the touch panel 302), and a plurality of third sensing conductors 3124 extended along the second direction D2 (e.g. the rows of the touch panel 302). The fourth region D comprises a plurality of fourth driving conductors 3126 extended along the first direction D1, and a plurality of fourth sensing conductors 3128 extended along the second direction D2. Preferably, a number of the first driving conductors 3022, a number of the second driving conductors 3026, a number of the third driving conductors 3122, and a number of the fourth driving conductors 3126 are identical, and a number of the first sensing conductors 3024, a number of the second sensing conductors 3028, a number of the third sensing conductors 3124, and a number of the fourth sensing conductors 3128 are identical. The intersections of the driving conductors 3022 and the sensing conductors 3024, or of the driving conductors 3026 and the sensing conductors 3028, or of the driving conductors 3122 and the sensing conductors 3124, or of the driving conductors 3126 and the sensing conductors 3128 are not physically and electrically contacted, forming the mutual capacitance sensing element of the touch panel 302.

A plurality of driving lines XAB[0:n] are electrically connected to the driving conductors 3022 and 3026, and a plurality of driving lines XCD[0:n] are electrically connected to the driving conductors 3122 and 3126. A plurality of first sensing lines YA[0:m] electrically connected to the first sensing conductors 3024, a plurality of second sensing lines YB[0:m] electrically connected to the second sensing conductors 3028, a plurality of third sensing lines YC[0:m] electrically connected to the third sensing conductors 3124, and a plurality of fourth sensing lines YD[0:m] electrically connected to the fourth sensing conductors 3128. The controller 301a outputs driving signals via the driving lines XAB[0:n] to the driving conductors 3022 and 3026, while the controller 301b outputs driving signals via the driving lines XCD[0:n] to the driving conductors 3122 and 3126. The controller 301a coupled to the sensing conductors 3024 and 3028 via the sensing lines YA[0:m] and YB[0:m] receives sensing signals, while the controller 301b coupled to sensing conductors 3124 and 3128 via the sensing lines YC[0:m] and YD[0:m] receives sensing signals.

The controller 301a outputs driving signals in an ordered sequence of the second direction D2 to drive the driving conductors 3022 and 3026, and receives sensing signals from the sensing conductors 3024 in an ordered sequence of a fourth direction D4 (or the first direction D1) and receives sensing signals from the sensing conductors 3028 in an ordered sequence of the first direction D1 (or the fourth direction D4). Meanwhile, the controller 301b outputs driving signals in an ordered sequence of the third direction D3 to drive the driving conductors 3122 and 3126, and receives sensing signals from the second sensing conductors 3124 in an ordered sequence of the fourth direction D4 (or the first direction D1), and receives sensing signals from the sensing conductors 3128 in an ordered sequence of the first direction D1 (or the fourth direction D4). When fingers, touch pens, or other objects make one or more contacts of the touch panel 302, a certain point of the intersection of sensing conductors 3024, 3028, 3124, 3128 and the driving conductors 3022, 3026, 3122, 3126 is bound to induce a capacitance coupling phenomenon to cause the sensing signals generated by the sensing conductors 3024, 3028, 3124, 3128 to produce voltage variations. After each of the driving conductors 3022, 3026, 3122, 3126 is scanned one by one, an exact touch position can be obtained. The controllers 301a and 301b determine a touch position according to the voltage variations of the sensing signals.

Since the controllers 301a and 301b output driving signals via the driving lines XAB[0:n] and XCD[0:n] to the first driving conductors 3022 in the first region A, to the second driving conductors 3026 in the second region B, to the third driving conductors 3122 in the third region C, and to fourth driving conductors 3126 in the fourth region D simultaneously, the scan rate is increased. In addition, since each of the controllers 301a and 301b controls one half of the area of the touch panel 302, meaning that each of the controllers 301a and 301b is responsible for one half of the capacitance of the touch panel 302, the touch panel device 300 can be well controlled by the controller 301a and 301b without using a single controller with higher detecting sensibility and cost.

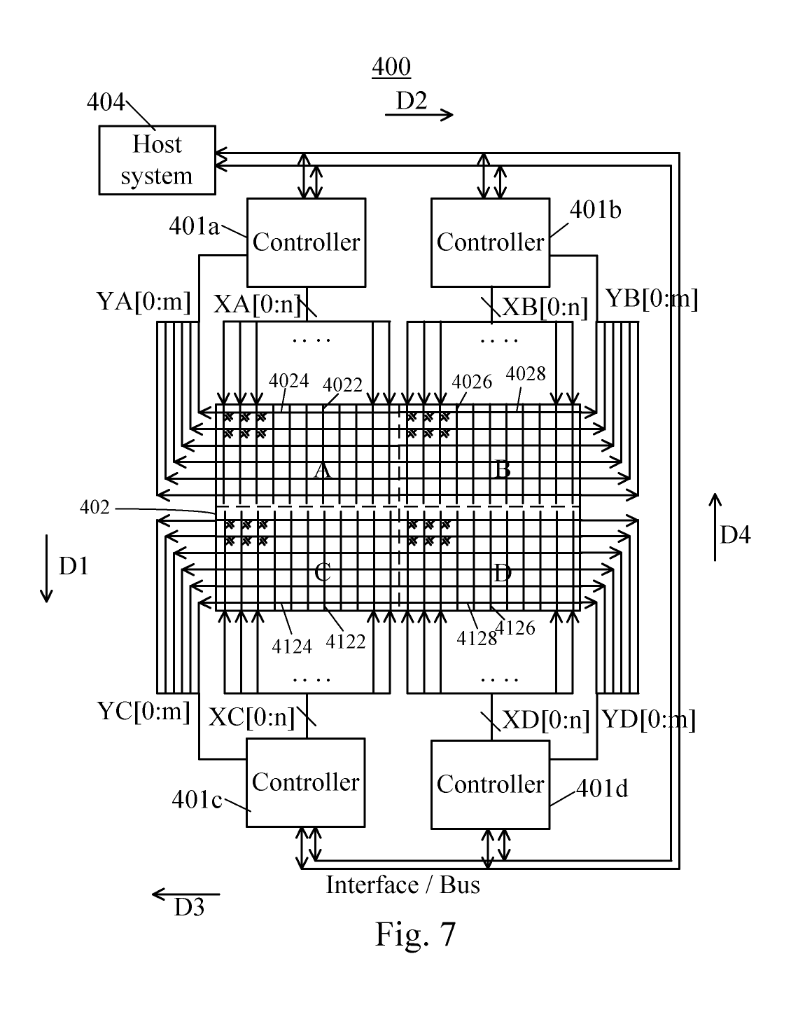

Please refer to FIG. 7, FIG. 7 illustrates a functional block diagram of a touch panel device 400 according to a fourth embodiment of the present invention. The touch panel device 400 comprises a control unit having four controllers 401a, 401b, 401c, and 401d, a touch panel 402, and a host system 404. For brevity, each of the controllers 401a, 401b, 401c, and 401d comprises a driving circuit, a sensing circuit, and I/O channels, all of which have the same function as that illustrated in FIG. 2 and are described above, so operation and label of the driving circuit and the sensing circuit is omitted. The host system 404 is used for controlling the operation of the touch panel device 400. The controllers 401a, 401b, 401c, and 401d, implemented by a digital signal processor (DSP) or a software program code, are used for determining a touch position and magnitude of a force applied on the touch panel 402.

The touch panel 402 comprises a first region A, a second region B, a third region C, and a fourth D. Each of the first region A, the second region B, the third region C, and the fourth region D comprises two layers of electrical conductors. The first region A comprises a plurality of first driving conductors 4022 extended along a first direction D1 (e.g. the columns of the touch panel 402), and a plurality of first sensing conductors 4024 extended along a second direction D2 (e.g. the rows of the touch panel 402) perpendicular to the first direction D1. The second region B comprises a plurality of second driving conductors 4026 extended along the first direction D1, and a plurality of second sensing conductors 4028 extended along the second direction D2. The third region C comprises a plurality of third driving conductors 4122 extended along the first direction D1 (e.g. the columns of the touch panel 402), and a plurality of third sensing conductors 4124 extended along the second direction D2 (e.g. the rows of the touch panel 402). The fourth region D comprises a plurality of fourth driving conductors 4126 extended along the first direction D1, and a plurality of fourth sensing conductors 4128 extended along the second direction D2. Preferably, a number of the first driving conductors 4022, a number of the second driving conductors 4026, a number of the third driving conductors 4122, and a number of the fourth driving conductors 4126 are identical, and a number of the first sensing conductors 4024, a number of the second sensing conductors 4028, a number of the third sensing conductors 4124, and a number of the fourth sensing conductors 4128 are identical. The intersections of the driving conductors 4022 and the sensing conductors 4024, or of the driving conductors 4026 and the sensing conductors 4028, or of the driving conductors 4122 and the sensing conductors 4124, or of the driving conductors 4126 and the sensing conductors 4128 are not physically and electrically contacted, forming the mutual capacitance sensing element of the touch panel 402.

A plurality of driving lines XA[0:n] are electrically connected to the driving conductors 4022, a plurality of driving lines XB[0:n] are electrically connected to the driving conductors 4026, a plurality of driving lines XC[0:n] are electrically connected to the driving conductors 4122, and a plurality of driving lines XD[0:n] are electrically connected to the driving conductors 4126. A plurality of first sensing lines YA[0:m] electrically connected to the first sensing conductors 4024, a plurality of second sensing lines YB[0:m] electrically connected to the second sensing conductors 4028, a plurality of third sensing lines YC[0:m] electrically connected to the third sensing conductors 4124, and a plurality of fourth sensing lines YD[0:m] electrically connected to the fourth sensing conductors 4128. In the meantime, the controller 401a outputs driving signals via the driving lines XA[0:n] to the driving conductors 4022; the controller 401b outputs driving signals via the driving lines XB[0:n] to the driving conductors 4026; the controller 401c outputs driving signals via the driving lines XC[0:n] to the driving conductors 4122; the controller 401d outputs driving signals via the driving lines XD[0:n] to the driving conductors 4126. The controller 401a coupled to the sensing conductors 4024 via the sensing lines YA[0:m] receives sensing signals. The controller 401b coupled to the sensing conductors 4028 via the sensing lines YB[0:m] receives sensing signals. The controller 401c coupled to sensing conductors 4124 via the sensing lines YC[0:m] receives sensing signals. The controller 401d coupled to sensing conductors 4128 via the sensing lines YD[0:m] receives sensing signals.

The controllers 401a and 401b synchronously output driving signals and output driving signals in an ordered sequence of the second direction D2 to drive the driving conductors 4022 and 4026. The controllers 401a receives sensing signals from the sensing conductors 4024 in an ordered sequence of a fourth direction D4 (or the first direction DD. The controllers 401b receives sensing signals from the sensing conductors 4028 in an ordered sequence of the first direction D1 (or the fourth direction D4). Meanwhile, the controller 401c and 401d synchronously output driving signals and output driving signals in an ordered sequence of the third direction D3 to drive the driving conductors 4122 and 4126. The controllers 401c receives sensing signals from the sensing conductors 4124 in an ordered sequence of a fourth direction D4 (or the first direction D1). The controllers 401d receives sensing signals from the sensing conductors 4128 in an ordered sequence of the first direction D1 (or the fourth direction D4).

When fingers, touch pens, or other objects make one or more contacts of the touch panel 402, a certain point of the intersection of sensing conductors 4024, 4028, 4124, 4128 and the driving conductors 4022, 4026, 4122, 4126 is bound to induce a capacitance coupling phenomenon to cause the sensing signals generated by the sensing conductors 4024, 4028, 4124, 4128 to produce voltage variations. After each of the driving conductors 4022, 4026, 4122, 4126 is scanned one by one, an exact touch position can be obtained. The controllers 401a, 401b, 401c, and 401d determine a touch position according to the voltage variations of the sensing signals.

Since the controllers 401a, 401b, 401c, and 401d output driving signals via the driving lines XA[0:n], XB[0:n], XC[0:n] and XD[0:n] to the first driving conductors 4022 in the first region A, to the second driving conductors 4026 in the second region B, to the third driving conductors 4122 in the third region C, and to fourth driving conductors 4126 in the fourth region D simultaneously, the scan rate is increased. In addition, since each of the controllers 401a, 401b, 401c, and 401d controls one fourth of the area of the touch panel 402, meaning that each of the controllers 401a, 401b, 401c, and 401d is responsible for one fourth of the capacitance of the touch panel 402, the touch panel device 400 can be well controlled by the controller 401a, 401b, 401c, and 401d without using a single controller with higher detecting sensibility and cost.

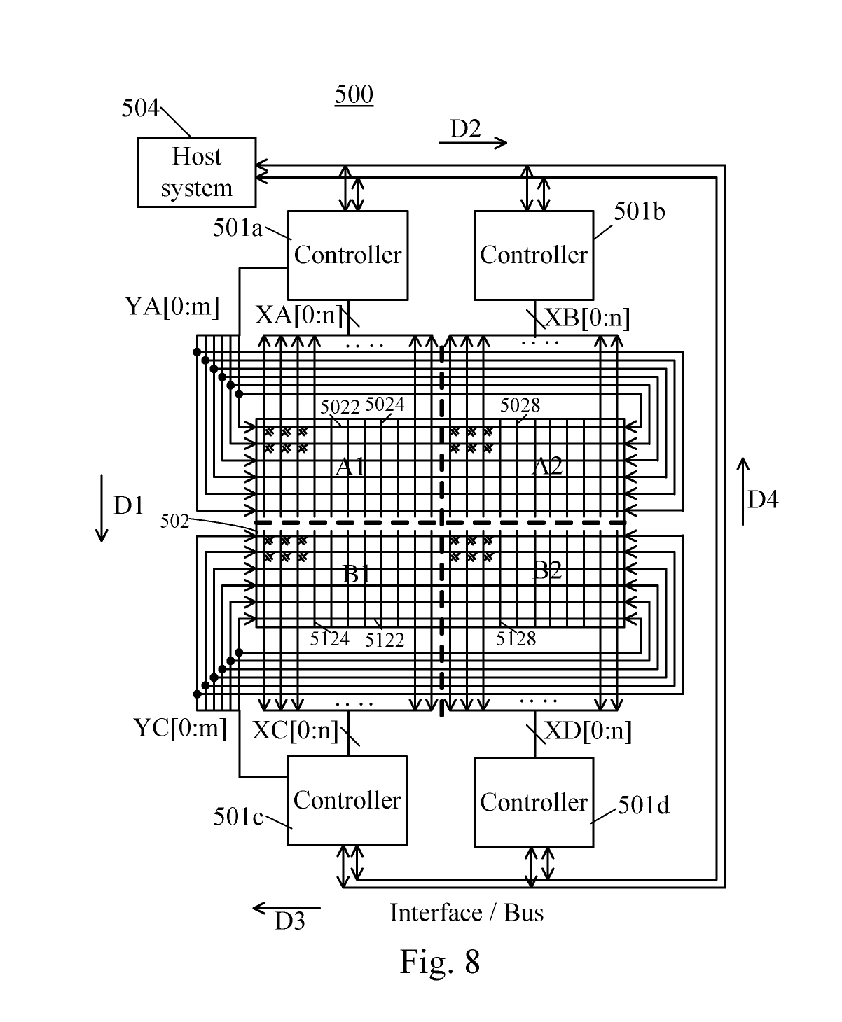

Please refer to FIG. 8, FIG. 8 illustrates a functional block diagram of a touch panel device 500 according to a fifth embodiment of the present invention. The touch panel device 500 comprises a control unit having four controllers 501a, 501b, 501c, and 501d, a touch panel 502, and a host system 504. For brevity, each of the controllers 501a, 501b, 501c, and 501d comprises a driving circuit, a sensing circuit, and I/O channels, all of which have the same function as that illustrated in FIG. 2 and are described above, so operation and label of the driving circuit and the sensing circuit is omitted. The host system 504 is used for controlling the operation of the touch panel device 500. Each of the controllers 501a, 501b, 501c, and 501d, implemented by a digital signal processor (DSP) or a software program code, is used for determining a touch position and magnitude of a force applied on the touch panel 502.

The touch panel 502 comprises a first region A1, a second region A2, a third region B1, and a fourth region B2. Each of the first region A1, the second region A2, the third region B1, and the fourth region B2 comprises two layers of electrical conductors. The first region A1 and the second region A2 shares a plurality of first driving conductors 5022 extended along a direction D2 (e.g. the rows of the touch panel 502). The first region A1 further comprises a plurality of first sensing conductors 5024 extended along a direction D1 (e.g. the columns of the touch panel 502) perpendicular to the direction D2 and controlled by the controller 501a. The second region A2 further comprises a plurality of second sensing conductors 5028 controlled by extended along a direction D1 and controlled by the controller 501b. The third region B1 and the fourth region B4 shares a plurality of second driving conductors 5122 extended along the direction D2. The third region B1 further comprises a plurality of third sensing conductors 5124 extended along a direction D1 (e.g. the columns of the touch panel 502) and controlled by the controller 501c. The fourth region B2 further comprises a plurality of fourth sensing conductors 5128 extended along a direction D1 and controlled by the controller 501d. Preferably, a number of the first driving conductors 5022 and a number of the second driving conductors 5122 are identical, and a number of the first sensing conductors 5024, a number of the second sensing conductors 5028, a number of the third sensing conductors 5124, and a number of the fourth sensing conductors 5128 are identical. The intersections of the driving conductors 5022 and the sensing conductors 5024 and 5028, or of the driving conductors 5122 and the sensing conductors 5124 and 5128 are not physically and electrically contacted, forming the mutual capacitance sensing element of the touch panel 502.

A plurality of driving lines YA[0:m] are electrically connected to the driving conductors 5022, and a plurality of driving lines YC[0:m] are electrically connected to the driving conductors 5122. A plurality of first sensing lines XA[0:n] electrically connected to the first sensing conductors 5024, a plurality of second sensing lines XB[0:n] electrically connected to the second sensing conductors 5028, a plurality of third sensing lines XC[0:n] electrically connected to the third sensing conductors 5124, and a plurality of fourth sensing lines XD[0:n] electrically connected to the fourth sensing conductors 5128. In the meantime, the controller 501a outputs driving signals via the driving lines YA[0:m] to the driving conductors 5022; the controller 501c outputs driving signals via the driving lines YC[0:m] to the driving conductors 5122. The controller 501a coupled to the sensing conductors 5024 via the sensing lines XA[0:n] receives sensing signals. The controller 501b coupled to the sensing conductors 5028 via the sensing lines XB[0:n] receives sensing signals. The controller 501c coupled to sensing conductors 5124 via the sensing lines XC[0:n] receives sensing signals. The controller 501d coupled to sensing conductors 5128 via the sensing lines XD[0:n] receives sensing signals.

The controllers 501a and 501c output driving signals in an ordered sequence of the second direction D1 to drive the driving conductors 5022 and 5122, and receives sensing signals from the sensing conductors 5024 and 5124 in an ordered sequence of a fourth direction D2 simultaneously. The controller 501b and 501d receives sensing signals from the second sensing conductors 5124 and 5128 in an ordered sequence of the fourth direction D2 as synchronous as the controllers 501a and 501c.

When fingers, touch pens, or other objects make one or more contacts of the touch panel 502, a certain point of the intersection of sensing conductors 5024, 5028, 5124, 5128 and the driving conductors 5022, 5122 is bound to induce a capacitance coupling phenomenon to cause the sensing signals generated by the sensing conductors 5024, 5028, 5124, 5128 to produce voltage variations. After each of the driving conductors 5022, 5122 is scanned one by one, an exact touch position can be obtained. The controllers 501a, 501b, 501c, and 501d determine a touch position according to the voltage variations of the sensing signals.

Since the controllers 501a and 501c output driving signals via the driving lines YA[0:m] and YC[0:m] to the first driving conductors 5022 in the first region A1 and A2, and to the second driving conductors 5122 in the second region B1 and B2, simultaneously, the scan rate is increased. In addition, since each of the controllers 501a and 501c controls one half of the area of the touch panel 502, meaning that each of the controllers 501a and 501c is responsible for one fourth of the capacitance of the touch panel 502, the touch panel device 500 can be well controlled by the controller 501a and 501c without using a single controller with higher detecting sensibility and cost.

Although the present invention has been explained by the embodiments shown in the drawings described above, it should be understood to the ordinary skilled person in the art that the invention is not limited to the embodiments, but rather various changes or modifications thereof are possible without departing from the spirit of the invention. Accordingly, the scope of the invention shall be determined only by the appended claims and their equivalents.

What is claimed is:

1. A touch panel device comprising:
a touch panel comprising:
a first region comprising a plurality of first driving conductors extended along a first direction, and a plurality of first sensing conductors extended along a second direction perpendicular to the first direction;
a second region comprising a plurality of second driving conductors extended along the first direction, and a plurality of second sensing conductors extended along the second direction; and
a control unit for outputting a plurality of driving signals in an ordered sequence of the second direction to drive the plurality of first driving conductors and the plurality of second driving conductors, and for receiving a plurality of sensing signals from the plurality of first sensing conductors and the plurality of second sensing conductors in an ordered sequence of the first direction.

2. The touch panel device as claimed in claim 1 further comprising a plurality of first driving lines electrically connected to the plurality of first driving conductors, a plurality of second driving lines electrically connected to the plurality of second driving conductors, a plurality of first sensing lines electrically connected to the plurality of first sensing conductors, and a plurality of second sensing lines electrically connected to the plurality of second sensing conductors.

3. The touch panel device as claimed in claim 2 wherein each of the first driving lines is electrically connected to one of the second driving lines, the control unit comprising a controller electrically connected to the first driving lines, the second driving lines, the first sensing lines, and the second sensing lines, the controller being used for outputting the plurality of driving signals via the first driving lines and the second driving lines to drive the plurality of first driving conductors and the plurality of second driving conductors, and for receiving the plurality of sensing signals from the plurality of first sensing conductors and the plurality of second sensing conductors.

4. The touch panel device as claimed in claim 2 wherein the control unit comprises:
a first controller electrically connected to the first driving lines and the first sensing lines;
a second controller electrically connected to the second driving lines and the second sensing lines,
the first and second controllers being used for outputting the plurality of driving signals via the first driving lines and the second driving lines to drive the plurality of first driving conductors and the plurality of second driving conductors, and for receiving the plurality of sensing signals from the plurality of first sensing conductors and the plurality of second sensing conductors.

5. A touch panel device comprising:
a touch panel comprising:
a first region comprising a plurality of first driving conductors extended along a first direction, and a plurality of first sensing conductors extended along a second direction perpendicular to the first direction;
a second region comprising a plurality of second driving conductors extended along the first direction, and a plurality of second sensing conductors extended along the second direction;
a third region comprising a plurality of third driving conductors extended along the first direction, and a plurality of third sensing conductors extended along the second direction;
a fourth region comprising a plurality of fourth driving conductors extended along the first direction, and a plurality of fourth sensing conductors extended along the second direction; and
a control unit for outputting a plurality of driving signals to drive the plurality of first driving conductors and the plurality of second driving conductors in an ordered sequence of the second direction, to drive the plurality of third driving conductors, the plurality of fourth driving conductors in an ordered sequence of a third direction opposite to the second direction, and for receiving a plurality of sensing signals from the plurality of first sensing conductors, the plurality of second sensing conductors, the plurality of third sensing conductors, the plurality of fourth sensing conductors.

6. The touch panel device as claimed in claim 5 wherein a number of the first driving conductors, a number of the second driving conductors, a number of the third driving conductors, and a number of the fourth driving conductors are identical, and a number of the first sensing conductors, a number of the second sensing conductors, a number of the third sensing conductors, and a number of the fourth sensing conductors are identical.

7. The touch panel device as claimed in claim 5 further comprising a plurality of first driving lines electrically connected to the plurality of first driving conductors, a plurality of second driving lines electrically connected to the plurality of second driving conductors, a plurality of first sensing lines electrically connected to the plurality of first sensing conductors, a plurality of second sensing lines electrically connected to the plurality of second sensing conductors, a plurality of third driving lines electrically connected to the plurality of third driving conductors, a plurality of fourth driving lines electrically connected to the plurality of fourth driving conductors, a plurality of third sensing lines electrically connected to the plurality of third sensing conductors, and a plurality of fourth sensing lines electrically connected to the plurality of fourth sensing conductors.

8. The touch panel device as claimed in claim 7 wherein each of the first driving lines is electrically connected to one of the second driving lines, and each of the third driving lines is electrically connected to one of the fourth driving lines.

9. The touch panel device as claimed in claim 8 wherein the control unit comprises:
a first controller electrically connected to the first driving lines, the second driving lines, the first sensing lines, and the second sensing lines, for outputting the plurality of driving signals via the first driving lines and the second driving lines to drive the plurality of first driving conductors and the plurality of second driving conductors, for receiving the plurality of sensing signals from the plurality of first sensing conductors in an ordered sequence of a fourth direction opposite to the first direction, and for receiving the plurality of sensing signals from the plurality of second sensing conductors in an ordered sequence of the first direction; and
a second controller electrically connected to the third driving lines, the fourth driving lines, the third sensing lines, and the fourth sensing lines, for outputting the plurality of driving signals via the third driving lines and the fourth driving lines to drive the plurality of third driving conductors and the plurality of fourth driving conductors, for receiving the plurality of sensing signals from the plurality of third sensing conductors in an ordered sequence of the fourth direction, and for receiving the plurality of sensing signals from the plurality of fourth sensing conductors in an ordered sequence of the first direction.

10. The touch panel device as claimed in claim 7 wherein the control unit comprises:
a first controller electrically connected to the first driving lines and the first sensing lines, for outputting the plurality of driving signals via the first driving lines to drive the plurality of first driving conductors in an ordered sequence of the second direction, and for receiving the plurality of sensing signals from the plurality of first sensing conductors in an ordered sequence of a fourth direction opposite to the first direction;
a second controller electrically connected to the second driving lines and the second sensing lines, for outputting the plurality of driving signals via the second driving lines to drive the plurality of second driving conductors in an ordered sequence of the second direction, and for receiving the plurality of sensing signals from the plurality of second sensing conductors in an ordered sequence of the first direction;
a third controller electrically connected to the third driving lines and the third sensing lines, for outputting the plurality of driving signals via the third driving lines to drive the plurality of third driving conductors in an ordered sequence of the third direction, and for receiving the plurality of sensing signals from the plurality of third sensing conductors in an ordered sequence of the fourth direction; and
a fourth controller electrically connected to the fourth driving lines and the fourth sensing lines, for outputting the plurality of driving signals via the fourth driving lines to drive the plurality of fourth driving conductors in an ordered sequence of the third direction, and for receiving the plurality of sensing signals from the plurality of fourth sensing conductors in an ordered sequence of the first direction.

11. The touch panel device as claimed in claim 8 wherein the control unit comprises:
a first controller electrically connected to the first driving lines and the first sensing lines, for outputting the plurality of driving signals via the first driving lines to drive the plurality of first driving conductors in an ordered sequence of the second direction, and for receiving the plurality of sensing signals from the plurality of first sensing conductors in an ordered sequence of the first direction;
a second controller electrically connected to the second driving lines and the second sensing lines, for receiving the plurality of sensing signals from the plurality of second sensing conductors in an ordered sequence of the first direction;
a third controller electrically connected to the third driving lines and the third sensing lines, for outputting the plurality of driving signals via the third driving lines to drive the plurality of third driving conductors in an ordered sequence of the second direction, and for receiving the plurality of sensing signals from the plurality of third sensing conductors in an ordered sequence of the first direction; and
a fourth controller electrically connected to the fourth driving lines and the fourth sensing lines, for receiving the plurality of sensing signals from the plurality of fourth sensing conductors in an ordered sequence of the first direction.
